(19) United States
(12) Patent Application Publication
(10) Pub. No.: US 2016/0007453 A1
(43) Pub. Date: Jan. 7, 2016

(54) HIGH THERMAL CONDUCTIVITY PREPREG, PRINTED WIRING BOARD AND MULTILAYER PRINTED WIRING BOARD USING THE PREPREG, AND SEMICONDUCTOR DEVICE USING THE MULTILAYER PRINTED WIRING BOARD

(71) Applicant: 3M INNOVATIVE PROPERTIES COMPANY, St. Paul, MN (US)

(72) Inventor: Kohichiro Kawate, Tokyo (JP)

(21) Appl. No.: 14/770,143

(22) PCT Filed: Feb. 25, 2014
(86) PCT No.: PCT/US2014/018157

§ 371 Date: Aug. 25, 2015

(30) Foreign Application Priority Data
Feb. 28, 2013 (JP) 2013-039287

(51) Int. Cl. H05K 1/03; H05K 1/18; H05K 1/11; H05K 1/02

(52) U.S. Cl. CPC H05K 1/0366; H05K 1/038; H05K 1/0298; H05K 1/185; H05K 1/181; H05K 1/115; H05K 1/0373; H05K 2201/10106; H05K 2201/0215; H05K 2201/0275

(57) ABSTRACT

Problem: To prepare a prepreg having high thermal conductivity and a low thermal expansion coefficient. Resolution Means: The prepreg of the present disclosure is composed of a composite layer including an alumina-containing cloth including ceramic fibers and a thermosetting resin composition impregnated into the alumina-containing cloth and having a thermal conductivity coefficient greater than or equal to 1.0 W/(mK).

### FIELD OF THE INVENTION

The present disclosure relates to a prepreg having high thermal conductivity, a printed wiring board and a multilayer printed wiring board using the prepreg, and a semiconductor device using the multilayer printed wiring board.

### BACKGROUND

Power semiconductor devices, including a substrate such as SiC and the like, are used as rectifiers or switches in power electronic circuits. Such devices generally require a printed wiring board (PWB) constructed of ceramic, for attaching the semiconductor chips. Such semiconductor chips generate a large amount of heat, and thus the PWB must be thermally conductive so that the PWB is able to conduct heat from the semiconductor chip to a heat sink.

FIG. 1 is a schematic cross-sectional view of the typical structure of a conventional power semiconductor module. A solder bond 134 is used to attach the semiconductor chip 130 to the ceramic printed wiring board 120, i.e. a laminate of a ceramic substrate 114 and an electrically conductive layer 122. At the opposite side of the ceramic printed wiring board 120, heat dissipation oil 138 is used to attach the ceramic printed wiring board 120 to a heat sink 136. The heat dissipation oil 138 is needed to compensate for differences in thermal expansion coefficients between the ceramic substrate 114 (thermal expansion coefficient of 4 to 6 ppm/° C.) and the heat sink 136 constructed of metal (thermal expansion coefficient of 15 to 20 ppm/° C.). The bottleneck of heat conduction in this structure is the heat dissipation oil 138. Typical thermal conductivity values of the materials used in the structure shown in FIG. 1 are as follows: solder=about 50 W/(mK), ceramic substrate=20 to 170 W/(mK), heat sink constructed of metal=about 390 W/(mK), and heat dissipation oil 1 to 3 W/(mK).

LED modules are cited as another application requiring high thermal conductivity. The junction temperature is important for the light emission efficiency of the LED, and changes in the junction temperature directly affect reliability and performance of the LED. Therefore, there is demand for increasing the thermal conductivity of the substrates used for mounting LED modules.

Patent Document 1 (Japanese Unexamined Patent Application Publication No. 2010-260990) mentions “a prepreg exhibiting a thermal conductivity greater than or equal to 0.5 W/(mK) and less than or equal to 30.0 W/(mK). The prepreg is composed of a core material and a composite agent used to impregnate this core material. The composite agent is composed of a semi-cured resin member, and inorganic filler dispersed in the resin member, and at least one type of wet dispersion agent. The fraction of the aforementioned composite agent in the prepreg is greater than or equal to 55% by volume and less than or equal to 95% by volume. The fraction of the aforementioned inorganic filler in the composite agent is greater than or equal to 35% by volume and less than or equal to 65% by volume. The aforementioned inorganic filler is selected as at least one type from among the group including magnesium oxide, magnesium carbonate, magnesium hydroxide, calcium carbonate, calcium oxide, aluminum hydroxide, alumina, aluminum nitride, boron nitride, silicon carbide, silicon nitride, silica, zinc oxide, titanium oxide, tin oxide, carbon, and zirconium silicate. Median particle diameter of the aforementioned inorganic filler is greater than or equal to 1 μm and less than or equal to 10 μm. BET specific surface area of the aforementioned inorganic filler is greater than or equal to 0.1 m²/g and less than or equal to 2.0 m²/g.”

Patent Document 2 (Japanese Unexamined Patent Application Publication No. 2010-229368) mentions “an epoxy resin composition including an epoxy resin (A), a phenolic novolac resin (B), an inorganic filler (C), and a silane coupling agent (D) having an amino group. Content of the aforementioned inorganic filler (C) relative to 100 parts by weight of the resin solids content is 150 to 950 parts by weight. Content of the aforementioned silane coupling agent (D) having an amino group relative to 100 parts by weight of the resin solids content is 0.3 to 1.5 parts by weight.”

Patent Document 3 (Japanese Unexamined Patent Application Publication No. 2009-101696) mentions “a copper foil laminate having a unified structure formed by attachment together of a prepreg sheet, copper foil, and a support sheet plate.”

### PRIOR ART DOCUMENTS

### Patent Documents

Patent Document 1: Japanese Unexamined Patent Application Publication No. 2010-260990

Patent Document 2: Japanese Unexamined Patent Application Publication No. 2010-229368

Patent Document 3: Japanese Unexamined Patent Application Publication No. 2009-101696

### SUMMARY OF THE INVENTION

### Problems to be Solved by the Invention

An object of the present invention is to provide a prepreg that has high thermal conductivity and a low thermal expansion coefficient. Separate objects of the present invention are to provide a printed wiring board and a multilayer printed wiring board using the aforementioned prepreg, and to provide a semiconductor device using the aforementioned multilayer printed wiring board.

### Means for Solving the Problem

In one embodiment of the present invention, a prepreg is provided that includes a composite layer including an alumina-containing cloth including ceramic fibers and a thermosetting resin composition having a thermal conductivity greater than or equal to 1.0 W/(mK) impregnated into the aforementioned alumina-containing cloth.

In another embodiment of the present invention, a printed wiring board is provided that includes a cured article of the aforementioned prepreg and at least one electrically conductive layer stacked at least partially on the aforementioned cured article.

In another embodiment of the present invention, a multilayer printed wiring board is provided that includes: the aforementioned printed wiring board; and at least one wiring pattern layer stacked on the printed wiring board and composed of an interlayer insulation layer and a second electrically conductive layer; where at least one of the second electrically conductive layers is electrically connected to at least one of the electrically conductive layers of the printed wiring board through a through hole or via connection penetrating through the interlayer insulation layer.

In yet another embodiment of the present invention, a semiconductor device is provided that includes: the aforementioned multilayer printed wiring board; and a semiconductor chip embedded in the multilayer printed wiring board; wherein the semiconductor chip is electrically connected to at least one of the electrically conductive layers of the printed wiring board, or at least to one of the second electrically conductive layers, which is connected electrically to at least one of the electrically conductive layers of the printed wiring board. Moreover, in a further separate embodiment of the present invention, a semiconductor device is provided that includes a semiconductor chip soldered to the second electrically conductive layer of the outermost wiring pattern layer and the aforementioned multiplayer wiring board.

### Effect of the Invention

Due to high thermal conductivity of the alumina ceramic fiber included in the alumina-containing cloth forming the prepreg of an embodiment of the present disclosure, it is possible for heat to be transmitted efficiently through the fibers forming the cloth, and thus this alumina-containing cloth has high thermal conductivity within the overall face of the cloth. Moreover, the alumina-containing cloth has high dimensional stability due to the fabric structure of the alumina-containing cloth. Thus the prepreg that is one embodiment of the present invention, which combines an alumina-containing cloth and a thermosetting resin composition having a specified thermal conductivity as an impregnated matrix, is unique in that this embodiment combines high thermal conductivity and a low thermal expansion coefficient. The prepreg of this embodiment of the present invention may be used with advantage for the production of various types of semiconductor devices or modules having excellent heat dissipation means such as attachment of the prepreg to the heat sink of a semiconductor chip, attachment of a semiconductor chip to a multilayer printed wiring board, embedding of a semiconductor chip in a multilayer printed wiring board, and the like.

Note that the description above should not be considered a complete disclosure of all embodiments of the present invention or of the advantages related to the present invention.

### BRIEF DESCRIPTION OF THE DRAWINGS

FIG. 1 is a schematic cross-sectional view showing a typical structure of a conventional power semiconductor module.

FIG. 2 is a cross-sectional view of a first exemplary prepreg of the present disclosure.

FIG. 3 is a cross-sectional view of a second exemplary prepreg of the present disclosure.

FIG. 4 is a cross-sectional drawing view of a first exemplary printed wiring board of the present disclosure.

FIG. 5 is a schematic cross-sectional view of a power semiconductor module using the printed wiring board of the present disclosure.

FIG. 6 is a cross-sectional view of a first exemplary multilayer printed wiring board of the present disclosure.

FIG. 7 is a cross-sectional view of a first exemplary semiconductor device of the present disclosure.

FIG. 8 is a cross-sectional view of a second exemplary semiconductor device of the present disclosure.

FIG. 9 is an SEM image of the cross-sectional view of the prepreg cured article of Example 3.

FIG. 10 shows data from the dynamic mechanical analysis of the prepreg cured articles of Example 3 and Comparative Example 1.

FIG. 11 shows data from the thermo-mechanical analysis of the prepreg cured articles of Example 3 and Comparative Example 1.

### DETAILED DESCRIPTION

A detailed description for the purpose of illustrating representative embodiments of the present invention is given below, but these embodiments should not be construed as limiting the present invention.

The prepreg that is an embodiment of the present invention includes a composite layer including an alumina-containing cloth including ceramic fibers and a thermosetting resin composition impregnated into the aforementioned alumina-containing cloth. The thermosetting resin composition has a thermal conductivity greater than or equal to about 1.0 W/(mK), and together with the alumina-containing cloth, this thermosetting composition imparts high thermal conductivity to the prepreg.

FIG. 2 shows a cross-sectional view of a first embodiment of a prepreg of the present disclosure. The composite layer 16 of the prepreg 10 is composed of the alumina-containing cloth 12 and the thermosetting resin composition 14 impregnated into the alumina-containing cloth 12

The alumina-containing cloth is made of ceramic fibers composed of alumina, and this alumina-containing cloth is a cloth such as a plain weave cloth, twill weave cloth, heavy duty twill cloth, satin weave cloth, and the like. The alumina-containing cloth may be formed by using a weaving machine to weave warp yarn and weft yarn. The ceramic fibers used to produce the alumina-containing cloth generally may be obtained in the form of roving (untwisted assembly of one or more strands of ceramic fibers) or a continuous tow (i.e. so-called yarn). The cloth structure of the alumina-containing cloth imparts high dimensional stability to the prepreg and the cured article of the prepreg. Moreover, due to continuity of the fibers composing the alumina-containing cloth, the prepreg and cured article thereof have high thermal conductivity within the entire surface of the prepreg and cured article thereof. A plain weave type alumina-containing cloth is advantageous due to excellent laser processability, strength, reliability of interlayer insulation of via holes, and the like.

The ceramic fibers are exemplified by alumina fibers, aluminosilicate fibers, aluminoborosilicate fibers, and combinations of such fibers. Methods for the production of alumina fibers, aluminosilicate fibers, and aluminoborosilicate fibers are widely known in this field of technology, as exemplified by the methods disclosed in U.S. Pat. No. 3,795,524, U.S. Pat. No. 4,047,965 and U.S. Pat. No. 4,954,462. Based on the theoretical oxide composition, the alumina fibers include at least about 99% by weight alumina (Al₂O₃) and about 0 to about 0.5% by weight silica (SiO₂). Suitable alumina fibers may be obtained from 3M Company, St. Paul, Minn., under the trade designation “NEXTEL 610”, for example. Based on the theoretical oxide composition, the aluminosilicate fibers preferably include about 67% by weight to about 77% by weight alumina and about 23% by weight to about 33% by weight silica. Such aluminosilicate fibers may be obtained from 3M Company under the trade designation “NEXTEL 550” and “NEXTEL 720”, for example. Cloth produced from aluminosilicate fibers may be obtained from NITIVY Co., Ltd., Tokyo, Japan, under the trade designation “Nitivy ALF 3030P”, for example. Based on the theoretical oxide composition, the aluminoborosilicate fibers preferably include about 55% by weight to about 75% by weight alumina, more than about 0% by weight up to about 45% by weight silica (preferably at least about 15% by weight and less than about 35% by weight), and more than about 0% by weight and up to about 25% by weight (preferably about 1% by weight to about 5% by weight) B₂O₃. The fraction of crystalline structure of the aluminoborosilicate fibers is preferably greater than or equal to about 50% by weight, preferably is greater than or equal to about 75% by weight, and most preferably is about 100% by weight. The aluminoborosilicate fibers may be obtained from 3M Company under the trade designation “NEXTEL 312” and “NEXTEL 440”, for example.

Since alumina has a high thermal conductivity coefficient, it is advantageous for the ceramic fibers to be alumina fibers, aluminosilicate fibers, or a combination of such fibers. Particularly advantageous alumina fibers are composed of at least about 99% by weight alumina, at least 99.5% by weight alumina, or at least about 99.8% by weight alumina.

The ceramic fibers may be a crystalline ceramic and/or a mixture of crystalline ceramic and glass (i.e. fibers composed of both crystalline ceramic and glassy phases). The alumina contained in the alumina-containing cloth may have various crystalline forms such as α type, γ type, δ type, θ type, and the like. However, due to high thermal conductivity coefficient, heat resistance, mechanical strength, and electrical insulation resistance, the a form (i.e. α-alumina) is advantageous.

Fiber diameter of the ceramic fibers is generally greater than or equal to about 3 μm and less than or equal to about 100 μm. From the standpoints of strength, processability, and the like, the fiber diameter is preferably greater than or equal to about 5 μm, or even greater than or equal to about 10 μm, and less than or equal to about 50 μm, or even less than or equal to about 15 μm.

Basis weight of the alumina-containing cloth (i.e. weight per 1 m²) may be set greater than or equal to about 40 g/m², greater than or equal to about 60 g/m², or even greater than or equal to about 100 g/m², and less than or equal to about 2,000 g/m², less than or equal to about 1,000 g/m², or even less than or equal to about 500 g/m². By setting the basis weight of the ceramic fibers in the aforementioned range, it is possible to fill the opening parts and ceramic inter-fiber spaces of the cloth using the thermosetting resin composition while imparting sufficient strength and dimensional stability to the prepreg. Tensile strength of the alumina-containing cloth in at least one direction among the warp direction and weft direction is preferably greater than or equal to about 100 MPa, greater than or equal to about 500 MPa, or even greater than or equal to about 1,000 MPa. Tensile strength of the alumina-containing cloth may be determined by using a tensile tester to pull the cloth at a speed of about 0.05 mm/minute and measuring the breaking load. It is advantageous for thermal expansion coefficient of the alumina-containing cloth in at least one direction among the warp direction and weft direction to be less than or equal to about 20 ppm/° C., less than or equal to about 15 ppm/° C., or less than or equal to about 10 ppm/° C. Thermal expansion coefficient of the alumina-containing cloth is preferably in the aforementioned range in both the warp yarn direction and weft yarn direction. The thermal expansion coefficient of the alumina-containing cloth may be determined by use of a thermo-mechanical analysis (TMA) apparatus by heating at a rate of about 10° C./minutes while applying a about 10 g weight.

The alumina-containing cloth may be pretreated by a surface treatment agent such as an epoxy-modified silane coupling agent or the like to increase wettability by the thermosetting resin composition, to increase the ability to bond with the thermosetting resin composition, and the like.

The thermosetting resin composition impregnated into the alumina-containing cloth and forming the matrix resin of the prepreg generally includes a thermosetting resin, a thermally conductive filler and, as may be required, a curing agent or the like.

Useable thermosetting resins are exemplified by epoxy resins, cyanate resins, bismaleimide resins, phenol resins, benzoxazine resins, vinyl benzyl ether resins, benzocyclotutene resins, polyvinyl acetal, and the like. In an embodiment of the present invention, an epoxy resin composition, including epoxy resin as the thermosetting resin, is used as the thermosetting resin composition.

Epoxy resins are exemplified by bisphenol epoxy resins such as bisphenol A type epoxy resins, bisphenol F type epoxy resins, and the like; novolac epoxy resins such as phenol novolac epoxy resins, cresol novolac epoxy resins, and the like; glycidyl amine type epoxy resins such as p-aminophenol triglycidyl ether and the like; alicyclic epoxy resins such as dicyclopentadiene epoxy resins, norbornene epoxy resins, adamantane epoxy resins, and the like; aryl alkylene epoxy resins such as xylylene epoxy resins, phenol aralkyl epoxy resins, biphenyl aralkyl epoxy resins, biphenyl dimethylene epoxy resins, glycidyl ethers of 1,1,2,2-(tetraphenol) ethane, and the like; naphthalene epoxy resins such as naphthalene skeleton-modified epoxy resins, methoxy naphthalene-modified cresol novolac epoxy resins, methoxynapthalene dimethylene epoxy resins, and the like; biphenyl epoxy resins such as biphenyl epoxy resins, tetramethyl biphenyl epoxy resins, and the like; anthracene epoxy resins; fluorene epoxy resins; phenoxy epoxy resins; flame-retardant epoxy resins formed by halogenation of the aforementioned epoxy resins; and the like; and combinations of such epoxy resins.

A suitable epoxy resin may be selected according to the properties required for the prepreg. For example, in an application requiring high heat resistance, advantageous epoxy resins include novolac epoxy resins such as phenol novolac epoxy resins, cresol novolac epoxy resins, and the like; biphenyl aralkyl type epoxy resins, naphthalene backbone-modified epoxy resins, and combinations of such epoxy resins. It is possible to increase adhesivity to other substrates such as the electrically conductive layer (e.g. copper foil and the like), heat sink, and the like by use of bisphenol epoxy resins such as bisphenol A type epoxy resins, bisphenol F type epoxy resins, rubber-modified bisphenol epoxy resins, and the like.

The epoxy equivalent weight of the epoxy resin may be set generally greater than or equal to about 100 g/equivalent, greater than or equal to about 120 g/equivalent, or even greater than or equal to about 150 g/equivalent, and less than or equal to about 1,000 g/equivalent, less than or equal to about 800 g/equivalent, or even less than or equal to about 500 g/equivalent. If a mixture of two or more types of epoxy resin is used, the aforementioned epoxy equivalent weight means the value of the mixture.

The average molecular weight of the epoxy resin, converted to a polystyrene standard, may be generally set greater than or equal to about 100 or even greater than or equal to about 200, and less than or equal to about 2,000, less than or equal to about 1,000, or even less than or equal to about 700. The average value of epoxy functionality of the epoxy resin, i.e. the average number of polymerization-capable epoxy groups per single molecule, is generally at least 2, and preferably is 2 to 4.

The epoxy resin may sometimes include trace amounts of chlorine derived from epichlorohydrin used in the synthesis process. In order to prevent contamination of the semiconductor element and corrosion, rusting and the like of the electrically conductive layer, solder, and the like, the content of chlorine in the epoxy resin is preferably less than or equal to about 1,500 ppm, and even less than or equal to about 1,000 ppm.

The content of the epoxy resin in the thermosetting resin composition, based on the solids content of the thermosetting resin composition, may be set greater than or equal to about 2% by weight, greater than or equal to about 5% by weight, or even greater than or equal to about 8% by weight, and less than or equal to about 30% by weight, less than or equal to about 20% by weight, or even less than or equal to about 15% by weight. By setting the content of the epoxy resin in the aforementioned range, it is possible to obtain the required toughness to the prepreg cured article, and to disperse the thermally conductive filler well in the prepreg, without impairing the high thermal conductivity of the alumina-containing cloth.

The thermally conductive filler is exemplified by alumina, aluminum nitride, boron nitride, silicon nitride, magnesium oxide, and the like. Alumina filler is preferably used due to its excellent thermal conductivity coefficient and moisture resistance. The alumina filler may have various crystalline forms such as α type, γ type, δ type, θ type, and the like. However, due to high thermal conductivity, heat resistance, mechanical strength, and electrical insulation resistance, the a form (i.e. α-alumina) is advantageous. Due to its high thermal conductivity coefficient, it is possible to use a nitride filler such as aluminum nitride, boron nitride, silicon nitride, and the like. A combination of an alumina filler and a nitride filler may be used.

Average particle size of the thermally conductive filler is determined such that the thermally conductive filler is able to fill the openings and ceramic inter-fiber spaces of the cloth. Average particle size of the thermally conductive filler is preferably greater than or equal to about 0.05 μm, greater than or equal to about 0.1 μm, or even greater than or equal to about 0.2 μm, and less than or equal to about 3 μm, less than or equal to about 2.5 μm, or even less than or equal to about 2 μm. By setting the average particle diameter of the thermally conductive filler in the aforementioned range, it is possible for the alumina-containing cloth to be loaded with a large amount of the thermally conductive filler, and it is possible to increase the thermal conductivity of the prepreg. Although a thermally conductive filler that has a single particle size distribution may be used, in order to increase the degree of loading of the filler, it is also permissible to use a combination of 2 or more fillers having different particle size distributions. For example, by use of a combination of a first thermally conductive filler of 1.5 μm average particle diameter and a second thermally conductive filler of 0.4 μm average particle diameter, it is possible to pack the second thermally conductive filler in the gaps between particles of the first thermally conductive filler. Thus, it is possible to increase the loading level of the thermally conductive fillers to a value higher than would be achieved by using a single thermally conductive filler having a single particle size distribution.

The content of the thermally conductive filler in the thermosetting resin composition, based on the solids content of the thermosetting resin composition, may be greater than or equal to about 80% by weight, greater than or equal to about 82% by weight, or even greater than or equal to about 84% by weight, and less than or equal to about 98% by weight, less than or equal to about 95% by weight, or even less than or equal to about 90% by weight. By setting the content of the thermally conductive filler in the aforementioned range, it is possible to disperse the thermally conductive filler well in the prepreg without impeding the high thermal conductivity of the alumina-containing cloth.

The thermosetting resin composition may also include a curing agent or a curing promotion agent. When an epoxy resin, for example, is used as the thermosetting resin, the curing agent is exemplified by known epoxy resin curing agents such as phenol type curing agents, aliphatic amines, aromatic amines, dicyandiamides, dicarboxylic acid dihydrazide compounds, acid anhydrides, and the like, and combinations of such epoxy resin curing agents. The curing promotion agent is exemplified by organic metal salts, tertiary amines, imidazoles, organic acids, onium salt compounds, and the like, and combinations of such curing promotion agents. Relative to 100 parts by weight of the epoxy resin, the utilized content of the curing agent and curing promotion agent is preferably greater than or equal to about 1 part by weight, or even greater than or equal to about 5 parts by weight, and less than or equal to about 20 parts by weight, or even less than or equal to about 10 parts by weight.

As may be required, the thermosetting resin composition may contain additives such as dispersants such as organic phosphates and the like; coupling agents such as modified silanes, organic titanates, and the like; antifoaming agents; leveling agents; antioxidants; flame retardants; and the like.

The thermal conductivity coefficient of the thermosetting resin composition is preferably greater than or equal to about 1.0 W/(mK), greater than or equal to about 1.5 W/(mK), or even greater than or equal to about 2.0 W/(mK), and less than or equal to about 15 W/(mK), or even less than or equal to about 10 W/(mK). Due to the thermal conductivity coefficient of the thermosetting resin composition being within the aforementioned range, along with the use of the alumina-containing cloth which itself has high thermal conductivity, it is possible to provide a prepreg having high thermal conductivity, without impairing the curing of the thermosetting resin composition. Thermal conductivity coefficient of the thermosetting resin composition may be determined based on ASTM E 1530.

A prepreg composed only of the composite layer may be produced by using a dispersion of the thermosetting resin composition in a solvent, treating the alumina-containing cloth with the dispersion and then removing the solvent. If the thermosetting resin is a liquid, it is possible to produce the prepreg by treating the alumina-containing cloth using the liquid thermosetting resin composition prepared without using a solvent. The thermosetting resin composition or dispersion thereof may be prepared using widely known mixing methods. When a solution is prepared, a solvent may be used as exemplified by acetone, methyl ethyl ketone (MEK), cyclohexanone (CHN), methyl isobutyl ketone (MIBK), cyclopentanone, dimethyl formamide (DMF), dimethyl acetoamide, N-methyl pyrrolidone, and the like. For example, the solvent may be used in a composition range of 1 to 100 parts by weight relative to 100 parts by weight of the solids content of the thermosetting resin composition. The method of using the thermosetting resin composition to impregnate the alumina-containing cloth is exemplified by immersion, coating, spraying, and the like. For good impregnation by the thermosetting resin composition, immersion is preferred. A semi-cured prepreg may be prepared by removing the solvent by heating for 1 to 10 minutes at a temperature of 90 to 180° C., for example.

Although no particular limitation is placed on thickness of the composite layer, this thickness may be set to greater than or equal to about 10 μm, greater than or equal to about 20 μm, or even greater than or equal to about 30 μm, and less than or equal to about 250 μm, less than or equal to about 200 μm, or even less than or equal to about 150 μm.

The prepreg may further have an adhesion promotion layer on the composite layer, as shown in FIG. 3. When an adhesion promotion layer is used, it is possible to improve adhesion to an electrically conductive layer (e.g. copper foil and the like) or to a different substrate such as a heat sink and the like. The adhesion promotion layer may be disposed at only one surface of the composite layer, or the adhesion promotion layer may be disposed at both surfaces of the composite layer. FIG. 3 shows a cross-sectional view of a second embodiment of a prepreg of the present disclosure, including prepreg 10 and adhesion promotion layers 18 at both faces of the composite layer 16.

The adhesion promotion layer includes a second thermosetting resin composition having a thermal conductivity coefficient greater than or equal to about 1.0 W/(mK). A composition similar to the aforementioned thermosetting resin composition may be used as the second thermosetting resin composition. Adhesive strength of the adhesion promotion layer may be increased by setting the content (% by weight) of thermally conductive filler of the second thermosetting resin lower than the content of thermally conductive filler of the thermosetting resin composition of the composite layer. Generally the second thermosetting resin composition of the adhesion promotion layer has higher adhesive strength and a lower thermal conductivity coefficient than the thermosetting resin composition of the composite layer. The thermal conductivity coefficient of the second thermosetting resin composition may be greater than or equal to about 1.0 W/(mK), greater than or equal to about 1.5 W/(mK), or even greater than or equal to about 2.0 W/(mK), and less than or equal to about 4 W/(mK), or even less than or equal to about 3 W/(mK).

The adhesion promotion layer may include core-shell particles. It is possible to increase adhesiveness of the adhesion promotion layer by the use of the core-shell particles. Thus, addition of the core-shell particles may compensate for the lowering of adhesiveness resulting from the use of a large amount of thermally conductive filler, and the thermal conductivity of the adhesion promotion layer may be increased to a higher value than would be attained without the use of core-shell particles.

Core-shell particles are a composite material that includes an internal core part and an external shell part, each of different materials. In the present invention, a core-shell rubber may be used in which glass transition temperature (Tg) of the shell part is higher than Tg of the core part. For example, the core part and the shell part materials may be selected such that Tg of the core part is greater than or equal to about −110° C. and less than or equal to about −30° C., and Tg of the shell part is greater than or equal to about 0° C. and less than or equal to about 200° C. For the present invention, Tg values of the core part material and shell part material are defined by the temperature of the peak of tan(δ) occurring during measurement of dynamic viscoelasticity.

The core-shell particles may have a core part composed of: polymers of conjugated dienes such as butadiene, isoprene, 1,3-pentadiene, cyclopentadiene, dicyclopentadiene, and the like; polymers of non-conjugated dienes such as 1,4-hexadiene, ethylidene-norbornene, and the like; and copolymers of such conjugated and non-conjugated dienes and aromatic vinyl compounds (such as styrene, vinyl toluene, α-methyl styrene, and the like), unsaturated nitrile compounds (such as acrylonitrile, methacrylonitrile, and the like), (meth)acrylates (such as 2-hydroxyethyl acrylate, 2-hydroxyethyl methacrylate, 3-hydroxybutyl acrylate, glycidyl methacrylate, butoxyethyl methacrylate, and the like); acrylic rubbers such as polybutyl acrylate; silicone rubbers; silicone rubbers; IPN type composite rubbers formed from silicone and polyalkyl acrylates. The core-shell particles may be a core-shell type graph copolymer in which the shell part surrounding the core part is formed by copolymerization of a (meth)acrylic acid ester with the periphery of the core part. Polybutadiene, butadiene-styrene copolymer, and acrylic-butadiene rubber-styrene copolymer may be used with advantage as the core part. Methyl(meth)acrylate may be used with advantage to form a graft copolymer as the shell part. The shell part is preferably layered, and the shell part may be composed of a single layer or multiple layers. Two or more types of core-shell particles may be used in combination as the core-shell particles.

Without particular limitation, such core-shell particles are exemplified by methyl methacrylate-butadiene copolymers, methyl methacrylate-butadiene-styrene copolymers, methyl methacrylate-acrylonitrile-butadiene-styrene copolymers, methyl methacrylate-acrylic rubber copolymers, methyl methacrylate-acrylic rubber-styrene copolymers, methyl methacrylate-acrylic-butadiene rubber copolymers, methyl methacrylate-acrylic-butadiene rubber-styrene copolymers, methyl methacrylate-(acrylic-silicone IPN rubber) copolymers, and the like. Methyl methacrylate-butadiene copolymers, methyl methacrylate-butadiene-styrene copolymers, and methyl methacrylate-acrylic-butadiene rubber-styrene copolymers may be used with advantage as the core-shell particles.

Average value of the primary particle diameter (weight average particle diameter) of the core-shell particles is generally greater than or equal to about 0.05 μm, or even greater than or equal to about 0.1 μm, and less than or equal to about 5 μm, or even less than or equal to about 1 μm. The average value of the primary particle diameter of the core-shell particles for the present invention is determined from the value obtained by zeta potential particle diameter distribution measurement.

The content of core-shell particles in the second thermosetting resin composition, based on solids content of the second thermosetting resin composition, may be greater than or equal to about 0.1% by weight, greater than or equal to about 0.2% by weight, or even greater than or equal to about 0.5% by weight, and less than or equal to about 5% by weight, less than or equal to about 3% by weight, or even less than or equal to about 2% by weight.

Without particular limitation, the thickness of the adhesion promotion layer may be greater than or equal to about 1 μm, greater than or equal to about 2 μm, or even greater than or equal to about 5 μm, and less than or equal to about 50 μm, less than or equal to about 30 μm, or even less than or equal to about 20 μm.

The prepreg cured article obtained in the aforementioned manner, including the case of use of a curing promotion layer, has a thermal conductivity coefficient that is extremely high in comparison to the prepreg used for a conventional printed wiring board. The prepreg cured article has a thermal conductivity that is generally greater than or equal to about 2 W/(mK), greater than or equal to about 3 W/(mK), or even greater than or equal to about 5 W/(mK), and less than or equal to about 15 W/(mK), less than or equal to about 12 W/(mK), or even less than or equal to about 10 W/(mK). The prepreg cured article obtained in the aforementioned manner is unique in that the cured article simultaneously also has an extremely low thermal expansion coefficient. The prepreg cured article has a thermal expansion coefficient greater than or equal to about 1 ppm/° C., or even greater than or equal to about 2 ppm/° C., and less than or equal to about 10 ppm/° C., or even less than or equal to about 7 ppm/° C.

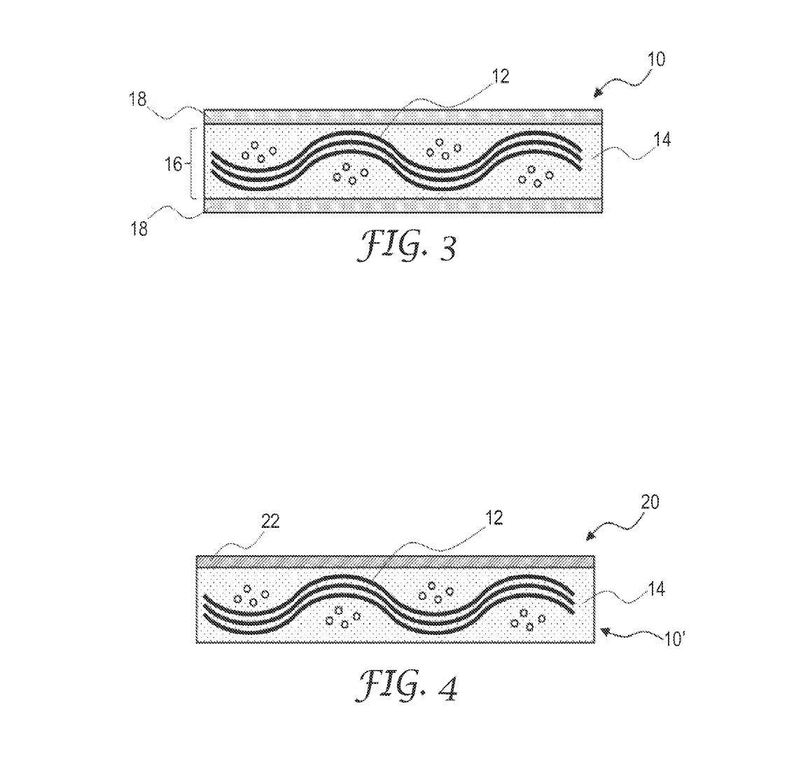

A printed wiring board may be produced using the prepreg of the present invention. The printed wiring board is composed of the prepreg cured article and at least one electrically conductive layer stacked on at least part of the cured article. FIG. 4 shows a cross-sectional view of a first embodiment of a printed wiring board of the present disclosure. The printed wiring board 20 has a prepreg cured article 10′ and an electrically conductive layer 22 stacked on the prepreg cured article 10′. The electrically conductive layer may be stacked on a cured laminate of multiple prepregs. The electrically conductive layer may be stacked on just one face of the prepreg cured article (i.e. single sided printed wiring board), or the electrically conductive layer may be stacked on both faces (i.e. double sided printed wiring board). In the case of lamination to both faces of the prepreg cured article, these electrically conductive layers may be electrically connected through a through hole.

The printed wiring board may be obtained, for example, by stacking metal foil, the electrically conductive layer, on a prepreg or a laminate of multiple prepregs, and then compressing the laminate at a pressure of about 0.5 to about 5 MPa while heating to a temperature of about 120 to about 220° C. The prepreg is cured by heating during such processing. The metal foil is exemplified by copper, copper type alloy, aluminum, aluminum type alloy, silver, silver type alloy, gold, gold type alloy, zinc, zinc type alloy, nickel, nickel type alloy, tin, tin type alloy, iron, iron type alloy, and the like. An electrically conductive layer of the desired circuit pattern may be formed from the stacked metal foil by use of widely known procedures such as screen printing, photolithography-etching, laser processing, and the like (subtractive method). Rather than stacking of metal foil, it is permissible to cure the prepreg or a laminate of multiple prepregs, and thereafter form an electrically conductive layer having the circuit pattern using metal plating, such as copper, nickel, and the like, or an electrically conductive paste and the like (additive or semi-additive method).

Thickness of the printed wiring board is generally greater than or equal to about 50 μm, or even greater than or equal to about 100 μm, and less than or equal to about 1 mm, or even less than or equal to about 0.5 μm. Thickness of the electrically conductive layer is generally greater than or equal to about 5 μm, or even greater than or equal to about 18 μm, and less than or equal to about 2,000 μm, or even less than or equal to about 1,000 μm.

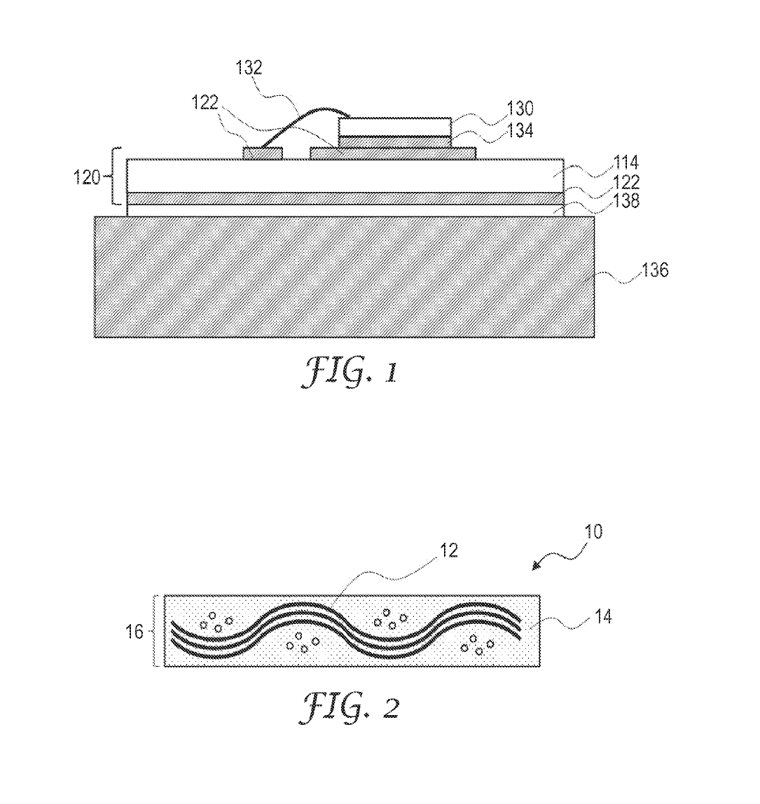

FIG. 5 shows an example of an application of the printed wiring board of the present disclosure. FIG. 5 shows a schematic cross sectional view of power semiconductor module. A semiconductor chip 30 is mounted on a heat sink 36 with a printed wiring board 20 therebetween. Printed wiring board 20 includes prepreg cured article 10′. The semiconductor chip 30 is respectively connected to the printed wiring board 20 and electrically conductive layer 22 by a bonding wire 32 and solder bond 34. This structure differs from the conventional structure shown in FIG. 1, for example, in that the heat sink is disposed at the side of the prepreg opposite to the side of attachment of the copper foil, and due to production beforehand of a laminated structure (i.e. copper foil/prepreg cured article/heat sink), it is possible to attach the heat sink 36 directly to the printed wiring board 20 without the use of the heat dissipation oil 138 (FIG. 1). It is thus possible for the heat sink to efficiently dissipate heat of the semiconductor chip from the heat sink. Moreover, since the thermal expansion coefficient of the semiconductor chip is similar to that of the prepreg cured article, it is possible to decrease thermal stress imparted to the mounted semiconductor chip.

It is possible to produce a multilayer printed wiring board by use of the printed wiring board of the present invention. For example, the printed wiring board may be used as a core board, and a multilayer printed wiring board may be produced by stacking thereon at least one wiring pattern layer composed of an interlayer insulation layer and a second electrically conductive layer. At least one of the second electrically conductive layers is electrically connected to at least one electrically conductive layer on the printed wiring board (i.e. core board) through a through hole or via connection penetrating the interlayer insulation layer. The multilayer printed wiring board of the present invention may be used with advantage for mounting semiconductors on a board (interposer) that has little thermal deformation and has high thermal conductivity.

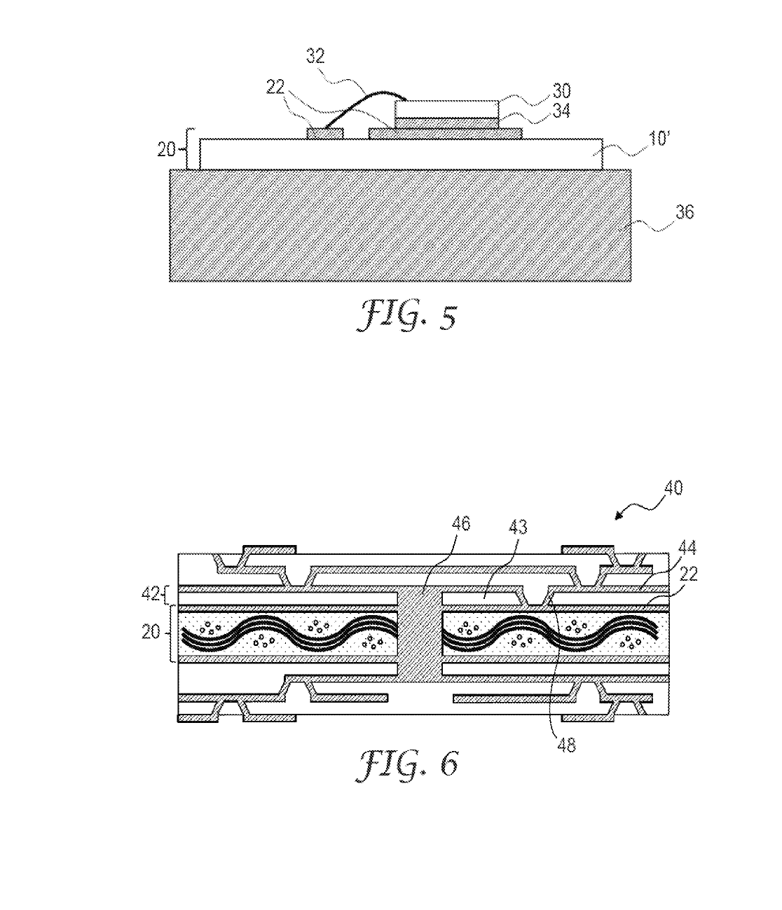

FIG. 6 shows a cross-sectional view of a first exemplary multilayer printed wiring board of the present disclosure. The multilayer printed wiring board 40 is composed of a printed wiring board 20 (core board) and a wiring pattern layer 42 stacked on the multilayer printed wiring board 40. The printed wiring board 20 includes electrically conductive layer 22. The wiring pattern layer 42 is composed of an interlayer insulation layer 43 and a second electrically conductive layer 44. Although FIG. 6 shows both a through hole 46 and a via connection 48, the multilayer printed wiring board may alternatively have just the through hole or just the via connection. As shown in FIG. 6, the second electrically conductive layer 44 is electrically connected to the electrically conductive layer 22 of the printed wiring board 20 through the through hole 46 and the via connection 48.

The interlayer insulation layer may be produced by forming a coating of a thermosetting epoxy resin composition on the core board or second electrically conductive layer and heating-curing the assembly, for example. Alternatively, the interlayer insulation layer may be produced by stacking a polyimide type film or the prepreg of the present invention on the core board or second electrically conductive layer, and then heating and curing the assembly. The second electrically conductive layer may be formed by the same methods as those of the aforementioned electrically conductive layer, for example. By using a laminate produced by stacking pattern-free or patterned metal foil on polyimide film or the prepreg of the present invention, it is possible to simultaneously form the interlayer insulation layer and the second electrically conductive layer. By the use of the prepreg of the present invention as the interlayer insulation layer, it is possible to obtain a multilayer printed wiring board that has higher thermal conductivity.

The through hole may be formed, for example, by opening a penetrating hole in the multiplayer printed wiring board by use of a drill, laser or the like, and then coating the inner wall of the through hole using an electrically conductive material. Alternatively, the entire through hole may be filled using electrically conductive material. After formation of the interlayer insulation layer on the core board, a via hole may be formed by laser light irradiation of the interlayer insulation layer. An oxidation agent (e.g. permanganate salts, dichromate salt, and the like) may then be used as part of the cleaning process (i.e. removal of interlayer insulation layer resin residue) and a via connection may be formed by plating the via hole and interlayer insulation layer surfaces using, for example, copper or the like. Plating may be performed by electroless plating alone, or may be performed by a combination or electroless plating and electrolytic plating. Photolithography may be used to form the via hole. The via hole may be entirely filled using a metal such as copper or the like (i.e. may be a filled via).

The multilayer printed wiring board may have solder resist in the outermost layer of the multilayer printed wiring board. The solder resist may be formed by stacking a film of solder resist or printing liquid resist, and then performing exposure and development, for example. As may be required, the multilayer printed wiring board may be cured after exposure and development (post-cure). On the second electrically conductive layer of the outermost wiring pattern layer of the multilayer printed wiring board, electrode parts may be provided for connection, in order to mount a semiconductor device. The electrode part for connection may be formed from a metal film by the plating of gold, nickel, solder, and the like.

Thickness of the multilayer printed wiring board is generally greater than or equal to about 50 μm or even greater than or equal to about 100 μm, and less than or equal to about 2 mm or even less than or equal to about 0.5 mm. The thickness of the core board of the multilayer printed wiring board is generally greater than or equal to about 30 μm, or even greater than or equal to about 50 μm, and less than or equal to about 500 μm, or even less than or equal to about 300 μm. Thickness of the interlayer insulation layer is generally greater than or equal to about 15 μm, or even greater than or equal to about 30 μm, and less than or equal to about 50 μm or even less than or equal to about 100 μm. Thickness of the second electrically conductive layer is generally greater than or equal to about 5 μm, or even greater than or equal to about 8 μm, and less than or equal to about 50 μm, or even less than or equal to 35 μm.

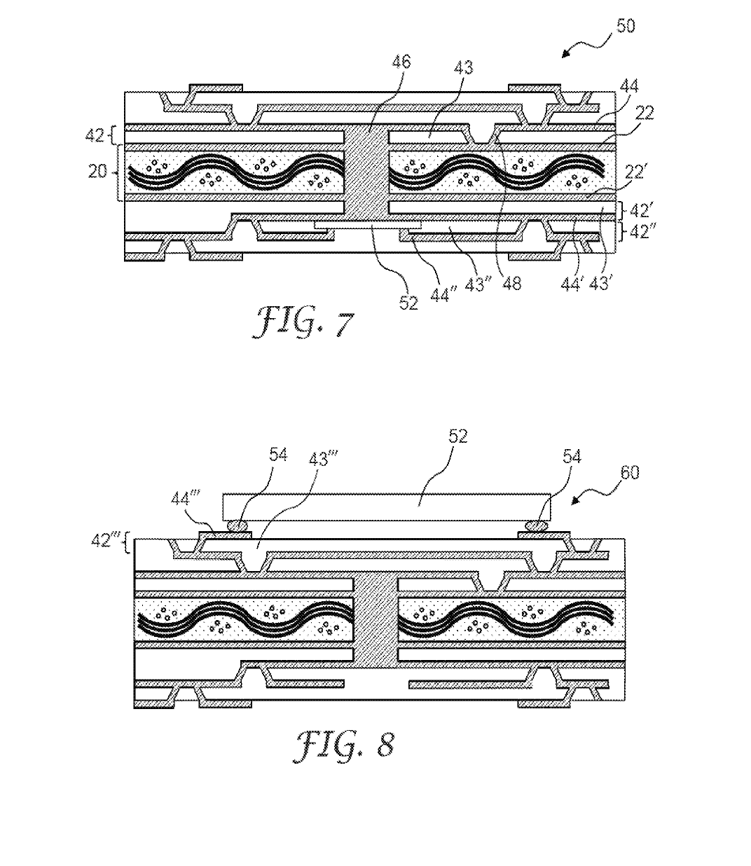

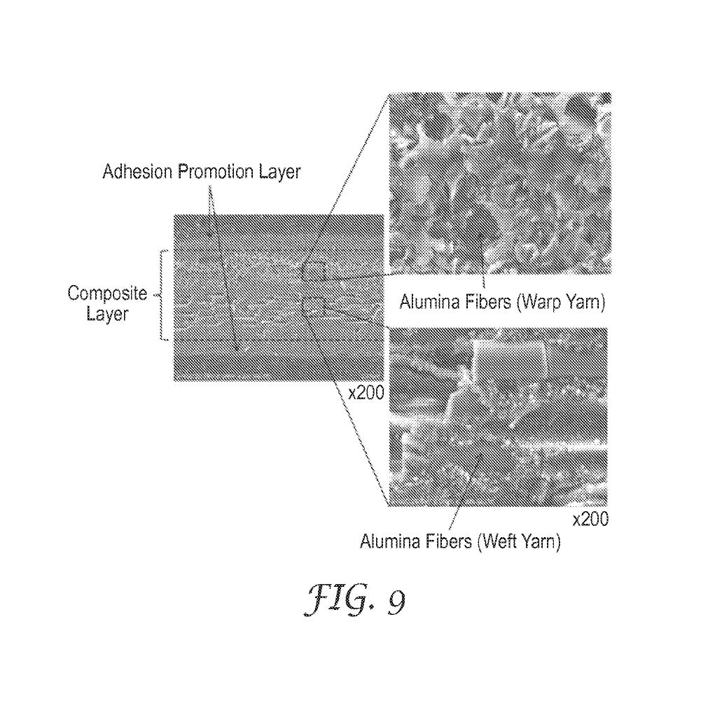

It is possible to produce a semiconductor device using the multilayer printed wiring board and semiconductor chip of the present invention. The semiconductor chip may be embedded in the multilayer printed wiring board, and the semiconductor chip may be electrically connected to the electrically conductive layer of the core board, or connected to at least one second electrically conductive layer connected electrically to the electrically conductive layer of the core board. Alternatively, the semiconductor chip may be soldered to the second electrically conductive layer of the outermost wiring pattern layer of the multilayer printed wiring board. Examples of such semiconductor devices are shown in FIG. 7 and in FIG. 8.

FIG. 7 is a cross-sectional view of a first exemplary semiconductor device 50 of the present disclosure. Semiconductor device 50 includes a semiconductor chip 52 embedded in a multilayer printed wiring board, as shown and described in FIG. 6. The multilayer printed wiring board contains wiring pattern layer 42, which includes an interlayer insulation layer 43 and a second electrically conductive layer 44; wiring pattern layer 42′, which includes an interlayer insulation layer 43′ and a second electrically conductive layer 44′; and wiring pattern layer 42″, which includes an interlayer insulation layer 43″ and a second electrically conductive layer 44″. Semiconductor chip 50 is connected electrically to the electrically conductive layer 44″ of wiring pattern layer 42″. In FIG. 7, the semiconductor chip 52 is contiguous with the through hole 46 but is not electrically connected to the through hole 46. In this embodiment, heat generated by the embedded semiconductor chip 52 may be dissipated to the printed wiring board 20 (core board) through the second electrically conductive layer 44″. When the semiconductor chip 52 is connected to an electrically conductive layer, e.g. second electrically conductive layer 44″, or a through hole, e.g. through hole 46, which is connected electrically to the electrically conductive layer 22′ of the printed wiring board 20, as shown in FIG. 7, it is possible to dissipate heat to the printed wiring board 20 with greater efficiency.

FIG. 8 is a cross-sectional view of a second exemplary semiconductor device 60 of the present disclosure. Semiconductor device 60 includes a semiconductor chip 52, wiring pattern layer 42′″, which includes an interlayer insulation layer 43′″ and a second electrically conductive layer 44′″, and solder bond 54. Semiconductor chip 52 is connected to second electrically conductive layer 44′″ through the solder bond 54. In FIG. 8, second electrically conductive layer 44′″ is considered to be part of the outermost wiring pattern layer. According to this embodiment, the thermal expansion coefficient of the core board is low, and it is thus possible to lower the thermal stress applied to the semiconductor chip.

Embedding of the semiconductor chip in the multilayer printed wiring board may be performed by methods widely known in this field of technology. For example, during formation of the multilayer printed wiring board, the semiconductor chip may be placed on an electrically conductive layer of the multilayer printed wiring board and a thermosetting epoxy resin composition may be printed at the periphery of the semiconductor chip, or the like. The thermosetting epoxy resin may then be heated and cured to form an interlayer insulation layer while leaving the electrode pads of the semiconductor chip exposed. Another electrically conductive layer having a circuit pattern may then be formed on the exposed portion of the semiconductor chip, producing a semiconductor device having a semiconductor chip embedded in a multilayer printed wiring board. Mounting of the semiconductor chip on the multilayer printed wiring board may be performed by methods widely known in this field of technology. For example, by use of the reflow method by placing a semiconductor chip having solder bumps composed of an alloy (composed of tin, lead, silver, bismuth, and the like) on the multilayer printed wiring board, and then by heating the assembly such that the solder bumps melt, it is possible to mount the semiconductor chip on the multilayer printed wiring board.

The prepreg of the present invention may be used for various types of printed wiring boards, multilayer printed wiring boards, and semiconductor devices. The prepreg of the present invention may be used particularly with advantage for the production of semiconductor devices that generate a large amount of heat, e.g. power semiconductor modules, LED modules, and the like.

### EXAMPLE

In the following examples, specific embodiments of the present disclosure are exemplified, but the present invention is not restricted thereto. All parts and percentages are based on weight unless otherwise indicated.

The reagents, raw materials, and the like used in these examples are shown below in Table 1.

TABLE 1

| Trade name | Description | Supplier |
|---|---|---|
| YDCN-700-3 | Creosol novolac epoxy resin | Nippon Steel & Sumikin |
| | Epoxy equivalent weight 195 to | Chemical Co., Ltd., Chiyoda- |
| | 205 | ku, Tokyo, Japan |
| ZX1059 | mixture of bisphenol A type epoxy | Nippon Steel & Sumikin |
| | resin and bisphenol F type epoxy | Chemical Co., Ltd., Chiyoda- |
| | resin (50/50) | ku, Tokyo, Japan |
| | Epoxy equivalent weight 160 to | |
| | 170 | |
| YD-825GS | bisphenol A epoxy resin | Nippon Steel & Sumikin |
| | Epoxy equivalent weight 170 to | Chemical Co., Ltd., Chiyoda- |
| | 190 | ku, Tokyo, Japan |
| EXL-2691A | Core shell particle, | The Dow Chemical Company, |
| | average particle diameter = 0.2 to | Midland, Michigan, United |
| | 0.3 μm, available under the trade | States |
| | designation “PARALOID | |
| | EXL-2691A” | |
| CG1200G | Hardening agent | Air Products Japan, Inc., |
| | Dicyandiamide | Allentown, Pennsylvania, US |
| TTS | Coupling agent, | Ajinomoto Fine Techno Co., |
| | organic titanate compound | Ltd., Kawasaki-shi, Tokyo, |
| | | Japan |
| Disperbyk111 | dispersant, | BYK Japan KK, Shinjyuku-ku, |
| | organic phosphate, available under | Tokyo, Japan |
| | the trade designation | |
| | “DISPERBYK 111” | |
| AA-1.5 | spherical alumina filler | Sumitomo Chemical |
| | (average particle diameter = 1.5 | Corporation, Chuoh-ku, |
| | μm) | Tokyo, Japan |
| AA-0.4 | spherical alumina filler | Sumitomo Chemical |
| | (average particle diameter 0.4 μm) | Corporation, Chuoh-ku, |
| | | Tokyo, Japan |
| CHN | cyclohexanone | Wako Pure Chemical |
| | | Industries, Ltd., Chuoh-ku, |
| | | Oosaka, Japan |
| Nextel | alumina cloth (100% α-alumina), | 3M Company |
| 610 (style DF-11) | available under the trade | |
| | designation “3M NEXTEL | |
| | 610 (style DF-11)”, | |
| | basis weight = 367 g/m² | |
| Nitivy ALF3030P | cloth of 72% alumina + 28% silica, | NITIVY Co., Ltd., Chuoh-ku, |
| | available under the trade | Tokyo, Japan |
| | designation “NITIVY ALF 3030P” | |
| | basis weight = 80 g/m² | |
| KBM-403 | glycidyl-modified silane coupling | Shin-Etsu Chemical Co., Ltd., |
| | agent | Chiyodaku, Tokyo, Japan |

A Planetary Centrifugal Mixer, ARE-310 manufactured by THINKY Corporation, Chiyoda-ku, Tokyo, Japan, was used to prepare cyclohexanone solutions of the thermosetting resin compositions 1 and 3 of the compositions listed below in Table 2, and the thermosetting resin composition 2 (solvent-free). After curing for 2 h at 150° C. and 1 h at 180° C., thermal conductivity coefficients of the thermosetting resin compositions 1, 2, and 3 were 2.4 W/(mK), 2.4 W/(mK), and 1.2 W/(mK), respectively.

TABLE 2
(all values based on parts by weight)

| | thermosetting | thermosetting | thermosetting |
|---|---|---|---|
| | resin | resin | resin |
| | composition 1 | composition 2 | composition 3 |
| YDCN-700-3 | 100 | | 75 |
| ZX1059 | | | 20 |
| YD-825GS | | 100 | |
| EXL-2691A | | | 5 |
| CG1200G | 8 | 8 | 8 |
| TTS | 6 | 6 | 6 |
| Disperbyk 111 | 3 | 3 | 3 |
| AA-1.5 | 550 | 650 | 480 |
| AA-0.4 | 100 | | 100 |
| solvent (CHN) | 100 | — | 75 |

### Example 1

3M Nextel 610 (style DF-11) was used as the alumina-containing cloth. The alumina-containing cloth was treated using a MEK solution containing 10% by weight of KBM-403 and then dried. Thereafter, the alumina-containing cloth was immersed in a cyclohexanone solution of the thermosetting resin composition 1, the alumina-containing cloth was passed through nip rollers and then was dried in an oven at 150° C. for 10 minutes to produce the prepreg of Example 1. The obtained prepreg had a thickness of 240 μm.

### Example 2

The prepreg of Example 2 was prepared in the same manner as Example 1 except for use of thermosetting resin composition 2 rather than the cyclohexanone solution of thermosetting resin composition 1, and using Nitivy ALF 3030P rather than 3M Nextel 610 (style DF-11) as the alumina-containing cloth. The obtained prepreg had a thickness of 160 μm.

### Example 3

A cyclohexanone solution of the thermosetting resin composition 3 was coated on TPX film (produced by Mitsui Chemicals Tohcello, Inc., Chiyoda-ku, Tokyo, Japan), and the assembly was dried for 10 minutes at 150° C. to produce a 15 μm thick adhesion promotion layer on TPX film. Thereafter, a heat laminator was used to stack the prepreg of Example 1 on the aforementioned adhesion promotion layer, and the TPX film was removed to produce the prepreg of Example 3. The obtained prepreg had a thickness of 270 μm.

### Comparative Example 1

FR-4 double-sided board R-1705 manufactured by Panasonic Corp., Kadoma-shi, Oosaka, Tokyo, Japan (without copper foil, 0.5 mm thick) was used as Comparative Example 1.

### <Evaluation Methods>

Characteristics of the prepreg of the present invention were evaluated by the below listed methods.

### <Thermal Conductivity Coefficient>

Thermal conductivity coefficient of the prepregs of Examples 1 through 3 and the thermal setting resin compositions 1 through 3 were calculated based on measurement using the laser flash analysis method, i.e. measurement of temperature at one side of the prepreg after laser irradiation of the opposite surface. Specifically, a thermal constant measurement apparatus (TC-7000, manufactured by ULVACK-Riko, Inc., Yokohama-shi, Kanagawa, Japan) was used to measure the thermal diffusivity (heat diffusion coefficient). A sample, having a 10 mm diameter and 0.25 mm thickness, was irradiated by laser light and the temperature at the backside was measured to find the heat diffusion coefficient. Specific heat was measured by DSC using a Q2000 V24.4 Build 116 DSC, available from TA Instruments, New Castle, Del., U.S.A. The DSC analysis was carried out at a temperature ramp of 10° C./min under a nitrogen atmosphere, 50 ml/min. Density of a sample was obtained by conventional mass and volume measurements.

The thermal conductivity coefficient was calculated by the following equation:

k=A×Cp×ρ

where k is the thermal conductivity coefficient (W/mK), A is the thermal diffusivity (m²/s), Cp is the specific heat (J/(KgK) and ρ is the density (kg/m3).

### <Adhesive Strength>

The prepreg was cut to produce a rectangular shaped sample (10 mm×15 mm) and then was placed on a 1 mm thick aluminum plate. Then a rectangular piece (10 mm×50 mm) of 18 μm thick copper foil was placed on the prepreg. The obtained laminate was pressed for 2 h at 50 kgf force and 150° C. temperature using a heat press. The laminate was further post-cured by heating for 1 h at 180° C. in an oven. Peel force was measured when the copper foil was peeled from the prepreg at 180° and 50 mm/minute using a Tensilon tester (manufactured by A & D Co., Ltd., Toshioma-ku, Tokyo, Japan), and this value was used as adhesive strength.

### <Dynamic Mechanical Analysis (DMA)>

Dynamic mechanical characteristics (DMA, i.e. storage elastic modulus E′ and loss elastic modulus E″) of the prepregs of Examples 1 through 3 were measured at 1 Hz in the 25 to 260° C. temperature range using a Solid Analyzer RSA-III (manufactured by Rheometric Scientific, Piscataway, N.J., U.S.A.). Temperature was raised stepwise in 3° C. increments, with temperature being maintained for 3 minutes at each temperature level. The utilized sample dimensions were 35 mm×10 mm×0.5 mm. Three-point bending measurement was performed by applying 0.05% deformation. Tg was defined as the value at the maximum of loss elastic modulus E″.

### <Thermo-Mechanical Analysis (TMA)>

The thermal expansion coefficient of the prepregs of Examples 1 through 3 were measured in the temperature range of 15 to 250° C. (heat-up rate of 10° C./minute) in nitrogen gas using a TMA Q400 (manufactured by TA Instruments, New Castle, Del., U.S.A.) as the thermo-mechanical analysis (TMA) apparatus. The TMA load was 10 g.

Results of evaluations of the prepregs of Examples 1 to 3 and Comparative Example 1 are shown in Table 3.

TABLE 3

| | | Thermal | | storage | Thermal |
|---|---|---|---|---|---|
| | | Conduc- | Adhe- | elastic | Expansion |
| | | tivity Co- | sive | modulus | Coeffi- |
| | Curing | efficient | force | (25° C., | cient |
| | conditions | (W/mK) | (N/cm) | GPa) | (ppm/° C.) |
| Example 1 | 150° C./2 h + | 5.7 | 8 | 60 | 3 |
| | 180° C./1 h | | | | |
| Example 2 | 150° C./2 h | 2.0 | 10 | 15 | 6 |
| Example 3 | 150° C./2 h + | 5.7 | 18 | 60 | 3 |
| | 180° C./1 h | | | | |
| Compar- | 150° C./2 h + | 0.3 | 19 | 20 | 11 |
| ative | 180° C./1 h | | | | |
| Example 1 | | | | | |

The sample produced by curing the prepreg of Example 3 for 2 h at 150° C. and then 1 h at 180° C. was embedded in a resin, available under the trade designation SCOTCHCAST RESIN NX-048 (manufactured by 3M Company, St. Paul, Minn.), and the assembly was cured for 24 h to produce a block. The obtained block was sliced using a diamond blade, and the sliced cross section was polished and observed. The cross-sectional surface observed by SEM is shown in FIG. 9.

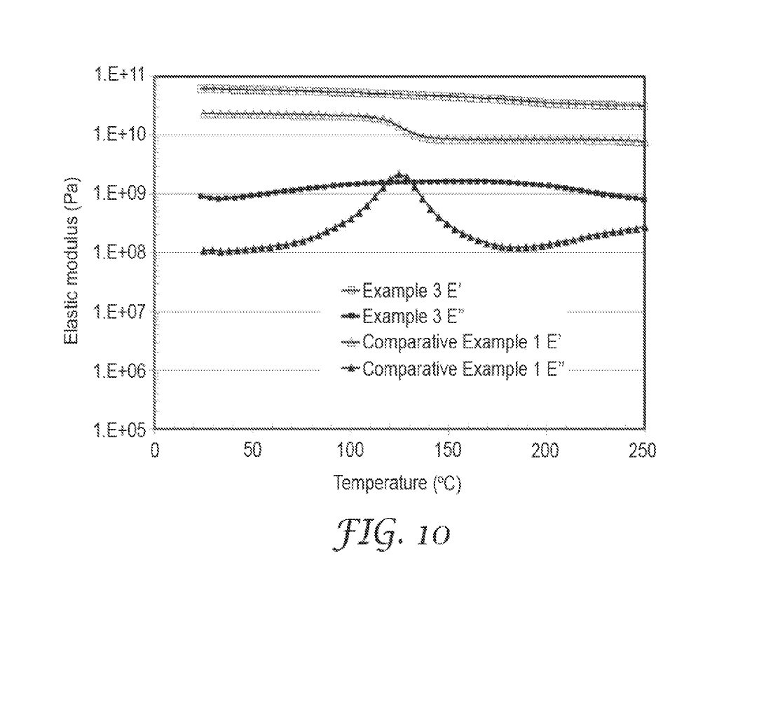

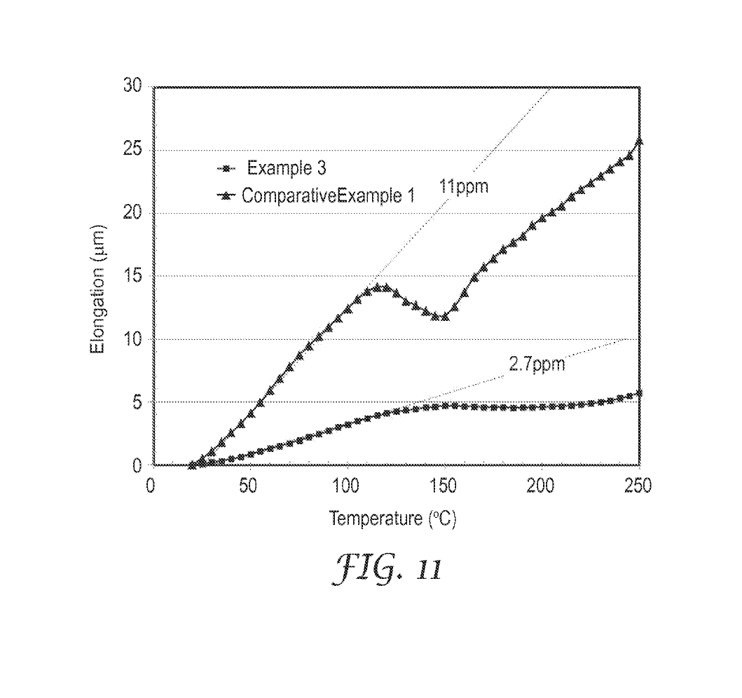

FIG. 10 shows the DMA data for Example 3 and Comparative Example 1. FIG. 11 shows the TMA data for Example 3 and Comparative Example 1.

1. A prepreg comprising:
a composite layer including an alumina-containing cloth comprising ceramic fibers; and
a thermosetting resin composition impregnated into the alumina-containing cloth and having a thermal conductivity coefficient greater than or equal to about 1.0 W/(mK).

2. The prepreg of claim 1, wherein the ceramic fibers comprise at least about 99% by weight alumina.

3. The prepreg of claim 1, wherein crystal structure of the alumina of the ceramic fibers is alpha type.

4. The prepreg of claim 1, wherein the thermal conductivity coefficient of the thermosetting resin composition is greater than or equal to about 2.0 W/(mK).

5. The prepreg of claim 1, wherein the thermosetting resin composition is an epoxy resin composition.

6. The prepreg of claim 1, wherein the thermosetting resin composition includes an alumina filler having an average particle diameter less than or equal to about 3 μm.

7. The prepreg of claim 1, wherein content of alumina filler in the thermosetting resin composition is greater than or equal to about 80% by weight.

8. The prepreg of claim 1, wherein basis weight of the alumina-containing cloth is about 40 to about 2,000 g/m².

9. The prepreg of claim 1, wherein the prepreg further comprises an adhesion promotion layer comprising a second thermosetting resin composition having a thermal conductivity coefficient greater than or equal to about 1.0 W/(mK).

10. The prepreg of claim 1, wherein the adhesion promotion layer further comprises core-shell particles.

11. A printed wiring board comprising:
the prepreg cured article of claim 1; and
at least one electronically conductive layer stacked on at least part of the prepreg cured article.

12. A multilayer printed wiring board comprising:
the printed wiring board of claim 11; and
at least one wiring pattern layer stacked on the printed wiring board and comprising an interlayer insulation layer and a second electrically conductive layer;
wherein at least one of the second electrically conductive layers is electrically connected to at least one of the electrically conductive layers of the printed wiring board through a through hole or via connection penetrating through the interlayer insulation layer.

13. A semiconductor device comprising:
the multilayer printed wiring board of claim 12; and
a semiconductor chip embedded in the multilayer printed wiring board;
wherein the semiconductor chip is electrically connected to at least one of the electrically conductive layers of the printed wiring board, or to at least to one of the second electrically conductive layers connected electrically to at least one of the electrically conductive layers of the printed wiring board.

14. A semiconductor device comprising:
the multilayer printed wiring board of claim 12; and
a semiconductor chip soldered to the second electrically conductive layer of the outermost wiring pattern layer.
